(19) United States
(12) Patent Application Publication
(10) Pub. No.: US 2007/0134928 A1
(43) Pub. Date: Jun. 14, 2007

(54) Silicon wet etching method using parylene mask and method of manufacturing nozzle plate of inkjet printhead using the same

(75) Inventors: Jae-chang Lee, Hwascong-si (KR); Chang-seung Lee, Yongin-si (KR); Jae-woo Chung, Yongin-si (KR); Duck-su Kim, Suwon-si (KR); Kyo-yeol Lee, Yongin-si (KR)

Correspondence Address: STANZIONE & KIM, LLP, 919 18TH STREET, N.W., SUITE 440, WASHINGTON, DC, 20006, US

(73) Assignee: SAMSUNG Electronics Co., Ltd., Suwon-si (KR)

(21) Appl. No.: 11/505,416

(22) Filed: Aug. 17, 2006

(30) Foreign Application Priority Data
Dec. 9, 2005 (KR) 2005-121124

(51) Int. Cl. H01L 21/302

(52) U.S. Cl. 438/745; 438/753

(57) ABSTRACT

A silicon wet etching method to form at least two elements having different shapes in a silicon substrate using at least two wet etching processes includes forming a first etch mask made of parylene on a surface of the silicon substrate, forming a first element in the substrate by wet etching the silicon substrate for a first time using the first etch mask, forming a second etch mask made of a silicon oxide layer on the surface of the silicon substrate, and forming a second element by wet etching the silicon substrate for a second time using the second etch mask.

### CROSS-REFERENCE TO RELATED APPLICATIONS

This application claims priority under 35 U.S.C. §119(a) from Korean Patent Application No. 10-2005-0121124, filed on Dec. 9, 2005, in the Korean Intellectual Property Office, the disclosure of which is incorporated herein in its entirety by reference.

### BACKGROUND OF THE INVENTION

1. Field of the Invention

The present general inventive concept relates to a silicon wet etching method, and more particularly, to a method of wet etching a silicon substrate using a parylene mask and a method of manufacturing a nozzle plate of an inkjet printhead using the same.

2. Description of the Related Art

A silicon oxide layer is used as an etch mask when wet etching a silicon substrate. The silicon oxide layer is formed at a predetermined thickness on a surface of the silicon substrate by thermally oxidizing the silicon substrate at a temperature of about 1000° C. Subsequently, an etch mask is formed by patterning the silicon oxide layer in a predetermined pattern using a photoresist. The silicon substrate is etched using an etchant for silicon (e.g., tetramethyl ammonium hydroxide (TMAH) or KOH) with the etch mask formed of the silicon oxide layer.

In some cases, two or more elements, such as grooves and holes, are formed in the silicon substrate using the wet etching. In these cases, when the elements have different aspect ratios and depths, two or more wet etching processes are repeatedly performed, and thus an etch mask required for each of the processes should be formed two or more times. Therefore, to form the silicon oxide layer as the etch mask, the silicon substrate undergoes repeated thermal oxidation process.

However, as the thermal oxidation process for the silicon substrate is repeated, a probability that the silicon substrate has a thermal defect due to penetration of an oxygen atom into an inside of the silicon substrate increases. When a defect is generated in the inside of the silicon substrate, etching uniformity at a portion where the defect has been generated and the neighborhood of the defect is reduced during a wet etching process for a subsequent element formed after a first element, and thus shape uniformity of an element formed on the portion where the defect has been generated is reduced.

### SUMMARY OF THE INVENTION

The present general inventive concept provides a silicon wet etching method to prevent a thermal defect from being formed in a silicon substrate to improve an etching uniformity by forming an etch mask using parylene deposited at room temperature.

The present general inventive concept also provides a method of manufacturing a nozzle plate of an inkjet printhead using the silicon wet etching method.

Additional aspects and advantages of the present general inventive concept will be set forth in part in the description which follows and, in part, will be obvious from the description, or may be learned by practice of the general inventive concept.

The foregoing and/or other aspects and utilities of the present general inventive concept may be achieved by providing a silicon wet etching method of forming at least two elements having different shapes in a silicon substrate using at least two wet etching processes, the method including forming a first etch mask made of parylene on a surface of the silicon substrate, forming a first element by wet etching the silicon substrate for a first time using the first etch mask, forming a second etch mask made of a silicon oxide layer on the surface of the silicon substrate, and forming a second element by wet etching the silicon substrate for a second time using the second etch mask.

The forming of the first etch mask may include depositing parylene on the surface of the silicon substrate to form a parylene layer, coating a first photoresist on the surface of the parylene layer and patterning the first photoresist to form a first opening corresponding to the first element, selectively removing the parylene layer exposed through the first opening to partially expose the surface of the silicon substrate, and removing the first photoresist.

The selective removing of the parylene layer may be performed by reactive ion etching O₂ ashing.

Each of the first and second wet etching may use one of tetramethyl ammonium hydroxide and KOH as an etchant.

The forming of the second etch mask may include forming a silicon oxide layer on the surface of the silicon substrate, coating a second photoresist on a surface of the silicon oxide layer and patterning the second photoresist to form a second opening corresponding to the second element, selectively etching the silicon oxide layer exposed through the second opening to partially expose the surface of the silicon substrate, and removing the second photoresist.

The silicon oxide layer may be formed by thermally oxidizing the silicon substrate.

The etching of the silicon oxide layer may be performed through reactive ion etching or wet etching using buffered oxide etchant BOE.

The foregoing and/or other aspects and utilities of the present general inventive concept may also be achieved by providing a method of manufacturing a nozzle plate of an inkjet printhead having a plurality of restrictors and a plurality of nozzles, the method including forming a first etch mask made of parylene on an upper surface of a silicon substrate, forming the plurality of restrictors in the silicon substrate by wet etching the upper surface of the silicon substrate for a first time using the first etch mask, forming a second etch mask made of a silicon oxide layer on the upper surface of the silicon substrate, forming dampers of each of the nozzles by wet etching the upper surface of the silicon substrate for a second time using the second etch mask, forming a third etch mask made of the silicon oxide layer on a lower surface of the silicon substrate, and forming an ink ejection port of each of the nozzles such that the ink ejection port communicates with the damper by dry etching the lower surface of the silicon substrate using the third etch mask.

The forming of the first etch mask may include, depositing parylene on the upper surface of the silicon substrate to form a parylene layer, coating a first photoresist on a surface of the parylene layer and patterning the first photoresist to form a plurality of first openings corresponding to the plurality of restrictors, selectively removing the parylene layer exposed through the first openings to partially expose the upper surface of the silicon substrate, and removing the first photoresist.

A corner portion of each of the restrictors may have a rounded shape.

The forming of the second etch mask may include, forming a silicon oxide layer on the upper surface of the silicon substrate, coating a second photoresist on an upper surface of the silicon oxide layer formed on the upper surface of the silicon substrate and patterning the second photoresist to form a plurality of second openings corresponding to the dampers, selectively etching the silicon oxide layer exposed through the second openings to partially expose the upper surface of the silicon substrate, and removing the second photoresist.

The forming of the third etch mask may include, forming a silicon oxide layer on the lower surface of the silicon substrate, coating a third photoresist on a lower surface of the silicon oxide layer formed on the lower surface of the silicon substrate and patterning the third photoresist to form a plurality of third openings corresponding to the dampers, selectively etching the silicon oxide layer exposed through the third openings to partially expose the lower surface of the silicon substrate, and removing the third photoresist.

The dry etching of the silicon substrate may be performed using inductively coupled plasma inductively coupled plasma reactive ion etching.

The foregoing and/or other aspects and utilities of the present general inventive concept may also be achieved by providing a nozzle plate of an inkjet printhead, including a plurality of restrictors, each restrictor having at least one rounded corner, to supply ink from a manifold to corresponding ones of a plurality of ink chambers of the inkjet printhead, and a plurality of nozzles to eject the ink from corresponding ones of the plurality of ink chambers.

Uniformity values of shapes of the plurality of restrictors may be about 0.1% to about 0.4%. The uniformity values of the shapes of the plurality of restrictors may be about 0.2% to about 0.3%. Each of the plurality of restrictors may have a rounded plane shape.

Each of the plurality of nozzles may include a damper formed in the upper portion thereof and having a pyramid shape having a cross-section that is gradually reduced towards the ink ejection port, and an ink ejection port formed in a lower portion thereof and having a vertical hole shape having a predetermined diameter. Each of the plurality of restrictors may be formed at a predetermined depth in an upper surface of the nozzle plate. Each of the plurality of restrictors may be formed at a predetermined depth of about 20 μm to about 40 μm in the upper surface of the nozzle plate.

The foregoing and/or other aspects and utilities of the present general inventive concept may also be achieved by providing a printhead, including a silicon substrate, including a plurality of ink chambers to contain ink to be ejected, and a manifold to supply the ink from an ink inlet to the plurality of ink chambers, and a nozzle plate disposed on a lower surface of the silicon substrate, including a plurality of restrictors, each restrictor having at least one rounded corner, to supply the ink from the manifold to corresponding ones of the plurality of ink chambers, and a plurality of nozzles to eject the ink from corresponding ones of the plurality of ink chambers.

The foregoing and/or other aspects and utilities of the present general inventive concept may also be achieved by providing a nozzle plate intermediate to form a nozzle plate of a printhead, including a silicon substrate having a plurality of restrictor openings etched therein, each restrictor opening having at least one rounded corner, and a parylene layer disposed on at least one surface of the silicon substrate.

The parylene layer may be disposed on at least two surfaces of the silicon substrate. The parylene layer may be disposed on an upper surface, a lower surface, and side surfaces of the silicon substrate.

The foregoing and/or other aspects and utilities of the present general inventive concept may also be achieved by providing a method of wet etching a silicon substrate using a parylene mask, including depositing a parylene layer at room temperature on an upper surface of a silicon substrate, forming a parylene mask by selectively etching portions of the parylene layer exposed through a photoresist, and wet etching portions of the silicon substrate exposed through the parylene mask to a predetermined depth.

The method may further include cleaning the at least one surface of the silicon substrate before depositing the parylene layer on the at least one surface. The at least one surface of the silicon substrate may be cleaned using an organic cleaning method.

The foregoing and/or other aspects and utilities of the present general inventive concept may also be achieved by providing a method of forming a nozzle plate of a printhead, including forming a plurality of restrictors in a surface of a silicon substrate by wet etching portions of the silicon substrate exposed through a parylene mask, each restrictor having at least one rounded corner, and forming a plurality of nozzles in the surface of the silicon by etching portions of the silicon substrate exposed through a second mask, each nozzle having a tapered shape.

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIG. 1A is a partially cut exploded perspective view illustrating a piezoelectric inkjet printhead formed using a silicon wet etching method according to the present general inventive concept;

FIG. 1B is a vertical sectional view illustrating a printhead taken along a line A-A′ of FIG. 1A;

FIG. 1C is a vertical sectional view illustrating the printhead taken along a line B-B′ of FIG. 1B;

FIGS. 2A through 2D are views illustrating an operation of forming a parylene mask as a silicon wet etching mask on a surface of a silicon substrate, according to an embodiment of the present general inventive concept;

FIG. 3 is a view illustrating an operation of a first wet etching of the silicon substrate of FIG. 2D using a parylene mask according to an embodiment of the present general inventive concept;

FIGS. 4A through 4D are views illustrating an operation of forming an etch mask made of a silicon oxide layer on a surface of the silicon substrate of FIG. 3 according to an embodiment of the present general inventive concept;

FIG. 5 is a view illustrating an operation of a second wet etching of the silicon substrate of FIG. 4D using a silicon oxide layer mask according to an embodiment of the present general inventive concept;

FIGS. 6A through 6C are views illustrating an operation of forming an ink ejection port of each of a plurality of nozzles on a lower surface of the silicon substrate of FIG. 5 according to an embodiment of the present general inventive concept;

FIGS. 7A through 7D are views comparing a shape of a restrictor formed in the operation illustrated in FIG. 3 according to an embodiment of the present general inventive concept with a shape of a conventional restrictor formed by a conventional method; and

FIG. 8 is a graph comparing uniformity of shapes of dampers formed according to an embodiment of the present general inventive concept and uniformity of shapes of conventional dampers formed by a conventional method.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures. In the drawings, thicknesses of layers and regions may be exaggerated for clarity.

An inkjet printhead ejects ink droplets onto a desired position of a recording medium to print an image of a predetermined color. The inkjet printhead may be generally classified into two types of printheads depending on ink ejecting methods: a thermally-driven inkjet printhead and a piezoelectric inkjet printhead. The thermally-driven inkjet printhead generates a bubble in ink using a heat source and ejects the ink using an expansion force of the bubble. The piezoelectric inkjet printhead deforms a piezoelectric element and ejects ink using a pressure applied to the ink due to the deformation of the piezoelectric element.

The embodiments described below described and illustrate silicon wet etching methods using a nozzle plate of a piezoelectric inkjet printhead. However, the present general inventive concept is not limited to these embodiments or to the piezoelectric inkjet printhead. Accordingly, the present general inventive concept may be applied to various substrates to which at least two or more elements (such as grooves, trenches, and holes) are formed therein.

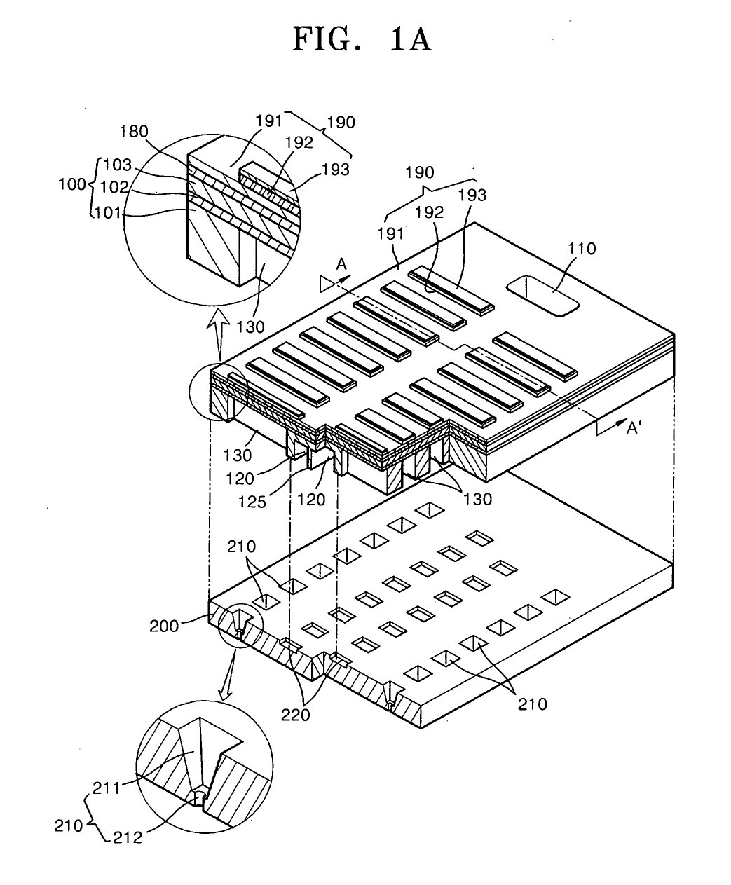

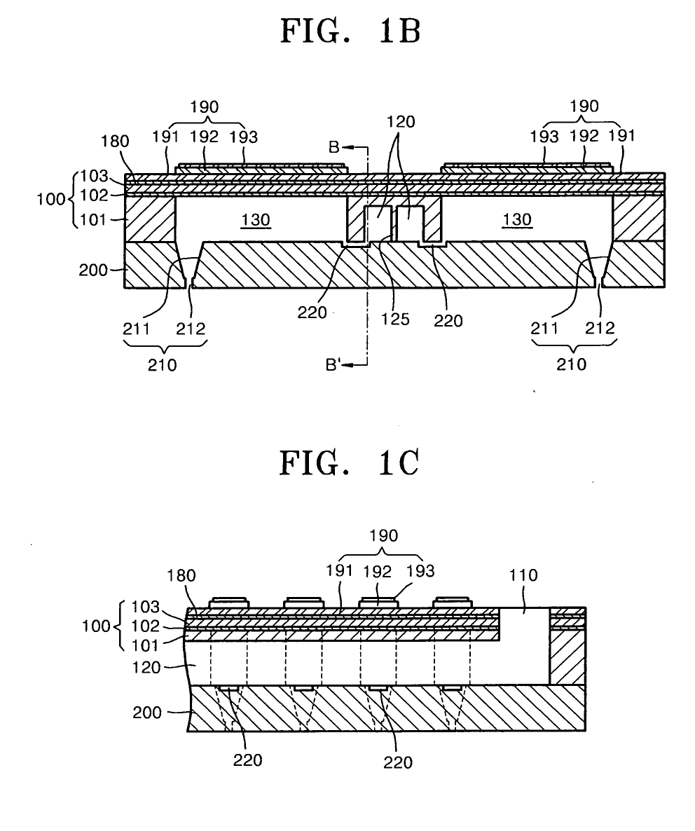

FIG. 1A is a partially cut exploded perspective view illustrating a piezoelectric inkjet printhead to which a silicon wet etching method according to the present general inventive concept is applied, FIG. 1B is a vertical sectional view illustrating the printhead taken along a line A-A′ of FIG. 1A, and FIG. 1C is a vertical sectional view illustrating a printhead taken along a line B-B′ of FIG. 1B.

Referring to FIGS. 1A through 1C, the piezoelectric inkjet printhead may include two substrates, i.e., an upper substrate 100 and a lower substrate 200 bonded to each other. An ink channel may be formed in the upper substrate 100 and the lower substrate 200, and a piezoelectric actuator 190 may be provided on an upper surface of the upper substrate 100 to generate a drive force required to eject ink.

Each of the two substrates 100 and 200 is formed of a single crystal silicon wafer. Therefore, it is possible to accurately and easily form elements constituting the ink channel with a finer size in the two substrates 100 and 200 using micromachining technology, such as photolithography and etching. Particularly, the upper substrate 100 may be formed of a silicon-on-insulator (SOI) wafer. The SOI wafer has a structure in which a first silicon layer 101, an intermediate oxide layer 102 formed on the first silicon layer 101, and a second silicon layer 103 bonded on the intermediate oxide layer 102 are stacked.

The ink channel may include an ink inlet 110 through which ink from an ink storage unit (not illustrated) flows, a plurality of pressure chambers 130 filled with ink to be ejected and to generate a pressure change required to eject the ink, a manifold 120 as a common channel to supply the ink flowing from the ink inlet 110 to the pressure chambers 130, a plurality of restrictors 220 as individual channels to supply ink from the manifold 120 to corresponding ones of the pressure chambers 130, and a plurality of nozzles 210 to eject ink from respective ones of the pressure chambers 130. The elements constituting the ink channel are distributed in the two substrates 100 and 200.

In detail, the ink inlet 110, the manifold 120, and the pressure chambers 130 are formed in the upper substrate 100. The manifold 120 is formed at a predetermined depth in a lower surface of the upper substrate 100 and has a shape extending in one direction. The ink inlet 110 is formed to vertically pass through the upper substrate 100 and to connect with one end of the manifold 120. The pressure chambers 130 are formed in the lower surface of the upper substrate 100 at a predetermined depth and arranged in two lines in both sides of the manifold 120. A partition wall 125 dividing the manifold 120 into right and left manifolds 120 (see FIG. 1B) to prevent cross-talk between the pressure chambers 130 may be formed long along a length direction of the manifold 120 inside of the manifold 120.

The piezoelectric actuator 190 may be formed on the upper substrate 100. Also, a silicon oxide layer 180 may be formed as an insulation layer between the upper substrate 100 and the piezoelectric actuator 190. The piezoelectric actuator 190 may include a lower electrode 191 to serve as a common electrode, a piezoelectric layer 192 to be deformed when a voltage is applied thereto, and an upper electrode 193 to serve as a drive electrode.

The plurality of restrictors 220 (which are individual channels to connect the manifold 120 with one end of each of the pressure chambers 130) and the plurality of nozzles 210 are formed in the lower substrate 200, thus forming a nozzle plate. The lower substrate 200 may be formed of a single crystal silicon wafer widely used to manufacture a semiconductor integrated circuit (IC) and may have a thickness of several hundred μm, e.g., a thickness of about 245 μm.

Each of the restrictors 220 is formed at a predetermined depth, e.g., 20-40 μm, in an upper surface of the lower substrate 200. One end of each of the restrictors 220 is connected to the manifold 120 and the other end of each of the restrictors 220 is connected to respective ones of the pressure chambers 130. Each of the resistors 220 supplies a desired amount of the ink from the manifold 120 to each of the pressure chambers 130 and suppresses the ink flowing backward from the pressure chambers 130 to the manifold 120 when the ink is ejected.

Each of the nozzles 210 may be formed at a position of the lower substrate 200 that corresponds to the other end of each of the pressure chambers 130 to vertically pass through the lower substrate 200. Each of the nozzles 210 may include a damper 211 formed in the upper portion of the lower substrate 200 and an ink ejection port 212 formed in a lower portion of the lower substrate 200 through which the ink is ejected. The ink ejection port 212 may be formed in a vertical hole shape having a predetermined diameter, and the damper 211 may be formed in a pyramid shape (e.g., a tapered shape) having a cross-section that is gradually reduced along a direction from the pressure chambers 130 to the ink ejection port 212.

The two substrates 100 and 200 are stacked and bonded to each other as described above to constitute the piezoelectric inkjet printhead according to the present embodiment. An ink channel formed by sequentially connecting the ink inlet 110, the manifold 120, the restrictors 220, the pressure chambers 130, and the nozzles 210 is formed in the inside of the two substrates 100 and 200.

A method of manufacturing a nozzle plate of an inkjet printhead having the above construction using a silicon wet etching method according to embodiments of the present general inventive concept will now be described.

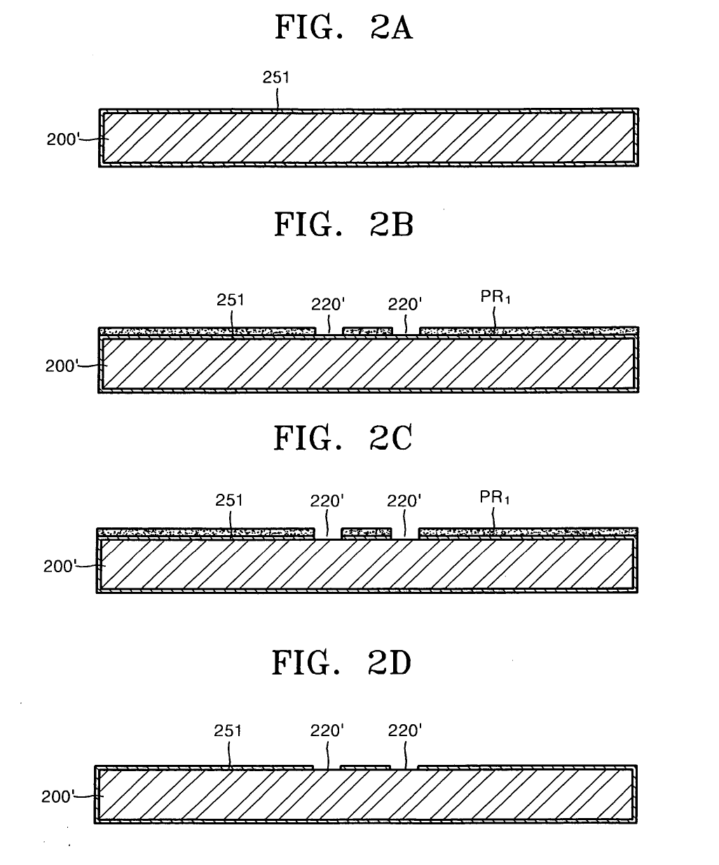

FIGS. 2A through 2D are views illustrating an operation of forming a parylene mask (layer) 251 as a silicon wet etching mask on a surface of a single crystal silicon substrate 200′ according to an embodiment of the present general inventive concept.

Referring to FIG. 2A, the single crystal silicon substrate 200′ having a thickness of about 650 μm is provided (such as the lower substrate 200 of FIG. 1A, hereafter referred to as a nozzle plate). Subsequently, the thickness of the silicon substrate 200′ is reduced to about 245 μm using chemical-mechanical polishing (CMP), and then the silicon substrate 200′ is cleaned. The cleaning of the silicon substrate 200′ may include an organic cleaning method using acetone or isopropyl alcohol (IPA), an acid cleaning method using sulphuric acid and buffered oxide etchant (BOE), and a standard clean 1 (SC1) cleaning method.

The parylene layer 251 having a predetermined thickness is formed on the surface of the cleaned silicon substrate 200′. Parylene is a chemical material that can be used as a coating material for semiconductors and has an advantage of easily being deposited on the surface of the silicon substrate 200′ at room temperature (i.e., about 20° C. to about 25° C.).

Next, referring to FIG. 2B, a photoresist PR1 is coated on the parylene layer 251 formed on the surface of the silicon substrate 200′. Subsequently, the coated photoresist PR1 is patterned to form a plurality of first opening 220′ intended to form a plurality of restrictors (such as the plurality of restrictors 220 of FIG. 1A) on the surface of the silicon substrate 200′. At this point, the pattering of the photoresist PR1 may be performed using well-known photolithography operations, such as exposing and developing operations. Patterning of other photoresists, which will be described below, may be performed using the same method described above.

Next, referring to FIG. 2C, the parylene layer 251 exposed through the first openings 220′ is selectively etched through reactive ion etching or O₂ ashing using the first photoresist PR1 as an etch mask to partially expose the surface of the silicon substrate 200′. Subsequently, the first photoresist PR1 is removed using the organic cleaning method and/or acid cleaning method. At this point, the first photoresist PR1 may be removed by ashing. The method of removing the first photoresist PR1 may be used to remove other photoresists, as described below.

Through the above processes, a first etch mask formed of a parylene layer 251 is formed on the surface of the silicon substrate 200′ as illustrated in FIG. 2D.

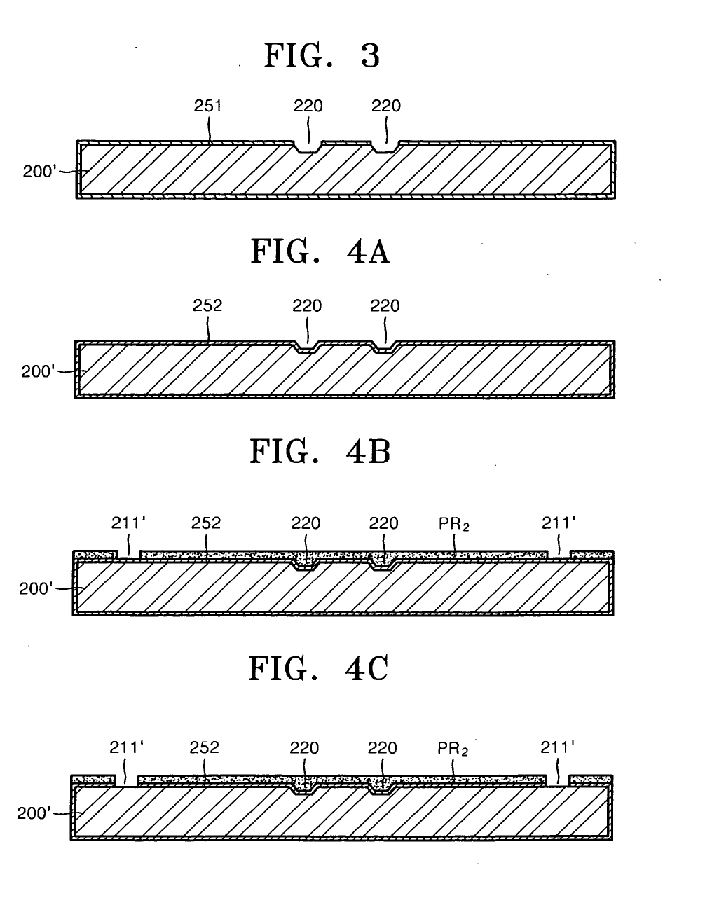

FIG. 3 is a view illustrating an operation of a first wet etching of the silicon substrate 200′ of FIG. 2D using a parylene mask (layer) 251 according to an embodiment of the present general inventive concept.

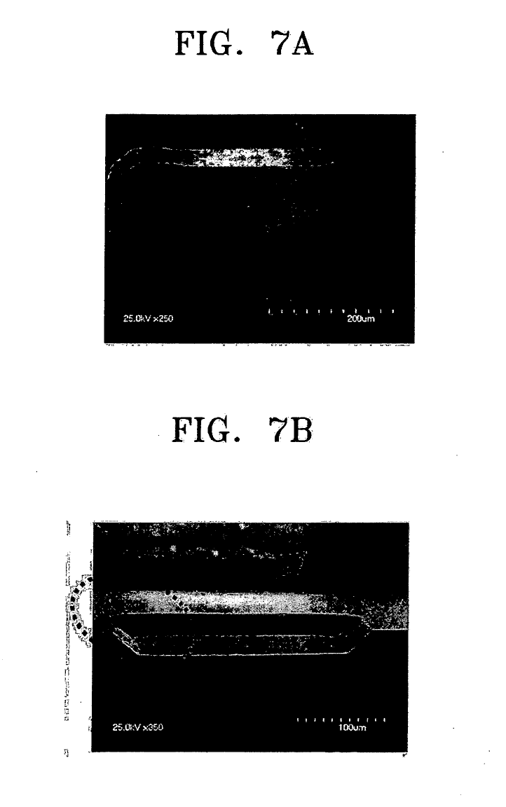

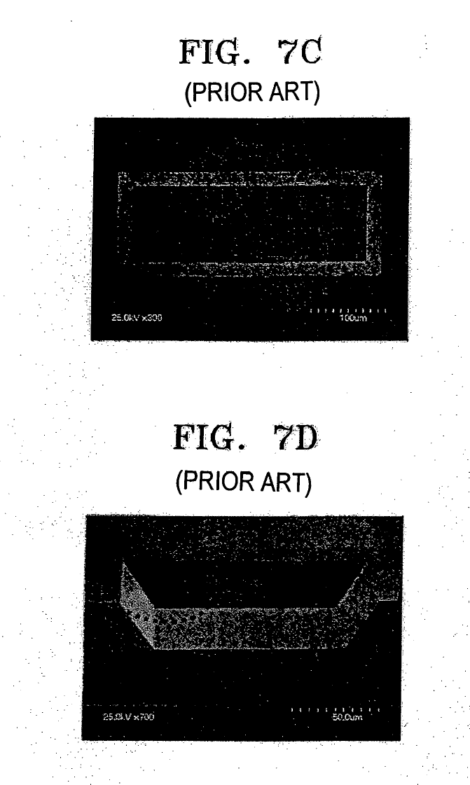

Referring to FIG. 3, an upper surface of the silicon substrate 200′ of FIG. 2D exposed through the first openings 220′ is wet etched in a first wet etching operation using the parylene layer 251 as a first etch mask to form a plurality of resistors 220, such that each of the resistors 220 has a groove shape of a predetermined depth. At this point, the wet etching of the silicon substrate 200′ may use tetramethyl ammonium hydroxide (TMAH) or KOH as an etchant. Furthermore, each of the restrictors 220 may have an inclined lateral surface and a rounded edge, which will be described later with reference to FIGS. 7A through 7D.

When the wet etching of the silicon substrate 200′ is completed, the parylene layer 251 is removed. At this point, the parylene layer 251 may be removed using RIE or O₂ ashing.

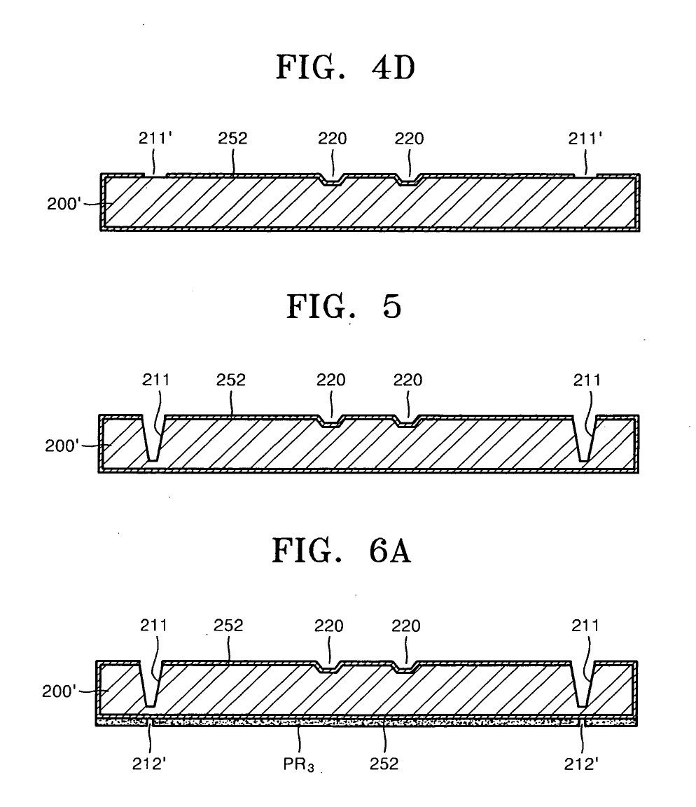

FIGS. 4A through 4D are views illustrating an operation of forming an etch mask made of a silicon oxide layer on the surface of the silicon substrate 200′ of FIG. 3 according to an embodiment of the present general inventive concept.

Referring to FIG. 4A, a silicon oxide layer 252 of a predetermined thickness is formed on the surface of the silicon substrate 200′ of FIG. 3 in which the plurality of resistors 220 are formed. The silicon oxide layer 252 may be formed by thermally oxidizing the silicon substrate 200′ at a temperature of about 1000° C.

Next, referring to FIG. 4B, a second photoresist PR2 is coated on a surface of the silicon oxide layer 252 formed on the surface of the silicon substrate 200′. Subsequently, the coated second photoresist PR2 is patterned to form a plurality of second openings 211′ intended to form a damper 211 (such as the damper 211 of FIG. 1A) of each of a plurality of nozzles (such as the nozzles 210 of FIG. 1A) on the surface of the silicon substrate 200′.

Next, referring to FIG. 4C, the silicon oxide layer 252 exposed through the plurality of second openings 211′ is selectively etched using the second photoresist PR2 for an etch mask to partially expose the surface of the silicon substrate 200′. At this point, the etching of the silicon oxide layer 252 may be performed through dry etching, such as RIE, or wet etching, such as using BOE. Subsequently, the second photoresist PR2 may be removed using the organic cleaning method and/or the acid cleaning method. At this point, the second photoresist PR2 may be removed by ashing.

Through the above processes, a second etch mask formed of the silicon oxide layer 252 is formed on the surface of the silicon substrate 200′ as illustrated in FIG. 4D.

FIG. 5 is a view illustrating an operation of second wet etching of the silicon substrate 200′ of FIG. 4D using a silicon oxide layer mask according to an embodiment of the present general inventive concept.

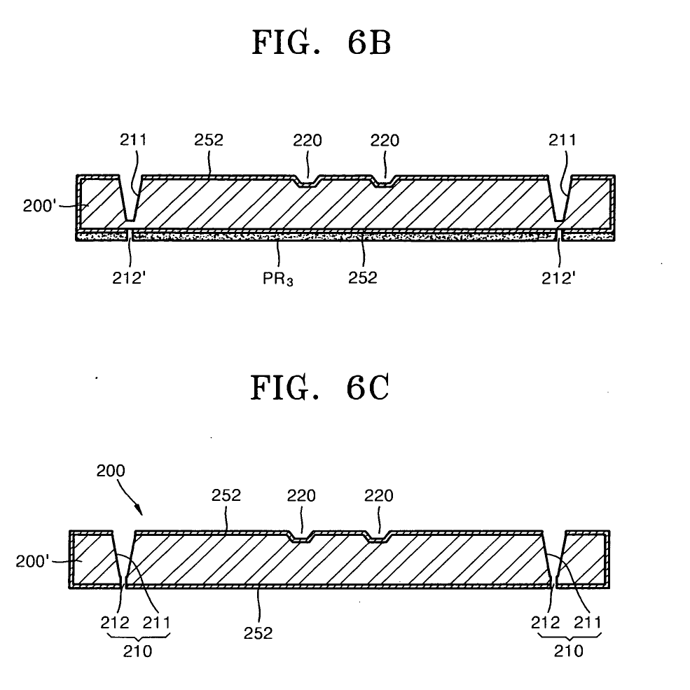

Referring to FIG. 5, the surface of the silicon substrate 200′ of FIG. 4D exposed through the second openings 211′ is wet etched in a second wet etching operation to a predetermined depth, e.g., a depth of 230-235 μm, using the silicon oxide layer 252 as a second etch mask to form a damper 211 of each of a plurality of nozzles 210 (see FIG. 6C). At this point, the wet etching of the silicon substrate 200′ may use tetramethyl ammonium hydroxide (TMAH) or KOH as an etchant. By doing so, the damper 211 having a pyramid shape may be formed by anisotropic wet etching characteristics depending on a crystal plane inside of the silicon substrate 200′ (e.g., as illustrated in FIG. 1A).

FIGS. 6A through 6C are views illustrating an operation of forming an ink ejection port of each of the plurality of nozzles 211 on a lower surface of the silicon substrate 200′ of FIG. 5.

Referring to FIG. 6A, a third photoresist PR3 is coated on the surface of the silicon oxide layer 252 formed on the lower surface of the silicon substrate 200′. Subsequently, the coated third photoresist PR3 is patterned to form a plurality of third openings 212′ intended to form the ink ejection port 212 (of FIG. 6C) of each of the plurality of nozzles 210 in the lower surface of the silicon substrate 200′.

Next, referring to FIG. 6B, the silicon oxide layer 252 exposed through the third openings 212′ is selectively wet etched or dry etched using the third photoresist PR3 as an etch mask to partially expose the lower surface of the silicon substrate 200′, and then the third photoresist PR3 is removed.

Next, referring to FIG. 6C, the partially exposed lower surface of the silicon substrate 200′ is etched such that the silicon substrate 200′ is pierced using the silicon oxide layer 252 formed on the lower surface of the silicon substrate 220′ as a third etch mask to form the ink ejection ports 212 communicating with the dampers 211. At this point, the etching of the silicon substrate 200′ may be performed using dry etching using, for example, inductively coupled plasma (ICP) RIE.

Through the above processes, it is possible to manufacture a nozzle plate 200 (such as the nozzle plate 200 of FIG. 1A) including the plurality of restrictors 220 formed in the upper surface of the silicon substrate 200′ and the plurality of nozzles 210 formed to pass through the silicon substrate 200′.

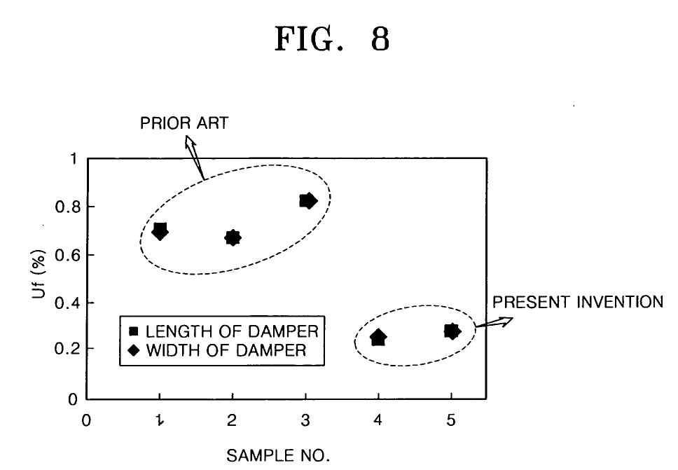

As described above, since the silicon wet etching method according to embodiments of the present general inventive concept performs a first wet etching process using a parylene mask, a number of times that a silicon substrate is subjected to thermal oxidization processes is reduced. Therefore, an occurrence of thermal defects inside of the silicon substrate 200′ that may be generated during the thermal oxidation process is prevented or reduced, and thus a uniformity of shape of a damper formed through a second wet etching process may be improved. Also, when the uniformity of shape of the damper is improved, a length of an ink ejection port may also be uniformly formed, so that an ink ejection performance is improved, an example of which will be described later with reference to FIG. 8.

FIGS. 7A through 7D are views comparing a shape of a restrictor formed in the operation illustrated in FIG. 3 according to an embodiment of the present general inventive concept with a shape of a restrictor formed by a conventional method.

FIGS. 7A and 7B illustrate a plane shape and a sectional shape of a resistor formed through the wet etching process using the parylene mask (layer) 251 illustrated in FIG. 3 according to an embodiment of the present general inventive concept, and FIGS. 7C and 7D illustrate a plane shape and a sectional shape of a resistor formed through a wet etching process using a silicon oxide layer mask according to the conventional method.

Due to anisotropic etching characteristics depending on a crystal plane, a restrictor has an inclined lateral surface. In detail, each of the restrictors of FIGS. 7A-7D has a lower surface whose miller index is (100) and a lateral surface whose miller index is (110).

However, according to the conventional method, since the silicon oxide layer has excellent bonding characteristics with the silicon substrate, very little etching in a horizontal direction is performed at a portion under the silicon oxide layer when the wet etching is performed. Therefore, an edge in a length direction of the conventional restrictor and an edge in a width direction of the conventional restrictor intersect almost at right angle, so that a plane shape of the conventional restrictor becomes a rectangle as illustrated in FIGS. 7C and 7D. In this case, there is a problem that a bubble may be trapped at sharp corner portions of each of the conventional restrictors when ink passes through each of the conventional resistors.

However, according to the present embodiment, since a bonding characteristics of the parylene layer 251 with respect to the silicon substrate 200′ is weaker than that of a silicon oxide layer with respect to the silicon substrate 200′, etching in a horizontal direction at the portion under the parylene layer 251 is more easily performed. Accordingly, corner portions of each of the restrictors may be rounded as illustrated in FIGS. 7A and 7B. In this case, the problem that a bubble is trapped at sharp corner portions of each of the restrictors when ink passes through each of the resistors may be minimized. Although the term “corner” generally relates to first and second edges that intersect to form an angle (e.g., the corners of the restrictor illustrated in FIG. 7C), the term “rounded corner” relates to first and second edges that intersect to form a rounded point of contact and not an angle (e.g., the rounded corners of the restrictor illustrated in FIG. 7A). Thus, the term “rounded corner” is a rounded point of contact formed at an intersection of two edges, and is not an angular point of contact formed at the intersection of the two edges.

FIG. 8 is a graph comparing uniformity of shape of dampers formed according to and embodiment of the present general inventive concept and uniformity of shape of dampers formed by a conventional method.

Referring to FIG. 8, uniformity of lengths and widths of the conventional dampers formed according to the conventional method (i.e., Samples 1-3) is about 0.7-0.8%, representing a relatively high uniformity value. On the contrary, uniformity of lengths and widths of the dampers formed according to the present embodiment (i.e., Samples 4 and 5) is about 0.1-0.4%, such as about 0.2-0.3%, representing a relatively low uniformity value. Since “uniformity” is defined by an average standard deviation, a uniformity of a shape of a damper is improved as a value of the uniformity is reduced. For example, the uniformity values of Samples 4 and 5 is lower than the uniformity values of Samples 1-3, and thus the uniformity of the shapes of Samples 4 and 5 is improved with respect to the uniformity of the shapes of Samples 1-3. Thus, the uniformity of the shapes of the dampers formed according to the present embodiment is improved with respect to the uniformity of the shapes of the dampers formed according to the conventional method.

As described above, according to embodiments of the present general inventive concept, a primary wet etching process is performed using a parylene mask deposited on a silicon substrate at room temperature, and a number of times that the silicon substrate is subjected to thermal oxidization processes is reduced. Therefore, thermal defects inside of the silicon substrate that may be generated during the thermal oxidation processes is minimized, and thus a shape uniformity of elements formed through the wet etching process may be improved.

According to embodiments of the present general inventive concept, when each of a plurality of restrictors is formed in a surface of a nozzle plate using the parylene mask, corner portions of each of the restrictors may be rounded and thus a problem that a bubble is trapped at the corner portions of each of the restrictors when ink passes through each of the resistors may be solved.

The piezoelectric inkjet printhead as illustrated and described above has been provided to improve an understanding of the present general inventive concept; however, the present general inventive concept is not limited to a piezoelectric inkjet printhead. That is, embodiments of the present general inventive concept may be readily applied to nozzle plates of various types of inkjet printheads, such as thermally-driven inkjet printheads. Also, embodiments of the present general inventive concept may be applied to form various elements (such as trenches, grooves, restrictors, holes, and nozzles) having various shapes in a silicon substrate using at least two wet etching processes.

Although a few embodiments of the present general inventive concept have been shown and described, it will be appreciated by those skilled in the art that changes may be made in these embodiments without departing from the principles and spirit of the general inventive concept, the scope of which is defined in the appended claims and their equivalents.

What is claimed is:

1. A silicon wet etching method to form at least two elements having different shapes in a silicon substrate using at least two wet etching processes, the method comprising:
forming a first etch mask made of parylene on a surface of the silicon substrate;
forming a first element by wet etching the silicon substrate for a first time using the first etch mask;
forming a second etch mask made of a silicon oxide layer on the surface of the silicon substrate; and
forming a second element by wet etching the silicon substrate for a second time using the second etch mask.

2. The method of claim 1, wherein the forming of the first etch mask comprises:
depositing parylene on the surface of the silicon substrate to form a parylene layer;
coating a first photoresist on the surface of the parylene layer and patterning the first photoresist to form a first opening corresponding to the first element;
selectively removing the parylene layer exposed through the first opening to partially expose the surface of the silicon substrate; and
removing the first photoresist.

3. The method of claim 2, wherein the selectively removing of the parylene layer is performed by reactive ion etching or O₂ ashing.

4. The method of claim 1, wherein each of the first and second wet etching uses one of tetramethyl ammonium hydroxide and KOH as an etchant.

5. The method of claim 1, wherein the forming of the second etch mask comprises:
forming a silicon oxide layer on the surface of the silicon substrate;
coating a second photoresist on a surface of the silicon oxide layer and patterning the second photoresist to form a second opening corresponding to the second element;
selectively etching the silicon oxide layer exposed through the second opening to partially expose the surface of the silicon substrate; and
removing the second photoresist.

6. The method of claim 5, wherein the silicon oxide layer is formed by thermally oxidizing the silicon substrate.

7. The method of claim 5, wherein the etching of the silicon oxide layer is performed through reactive ion etching or wet etching using buffered oxide etchant.

8. A method of manufacturing a nozzle plate of an inkjet printhead having a plurality of restrictors and a plurality of nozzles, the method comprising:
forming a first etch mask made of parylene on an upper surface of a silicon substrate;
forming the plurality of restrictors in the silicon substrate by wet etching the upper surface of the silicon substrate for a first time using the first etch mask;
forming a second etch mask made of a silicon oxide layer on the upper surface of the silicon substrate;
forming dampers of each of the nozzles by wet etching the upper surface of the silicon substrate for a second time using the second etch mask;
forming a third etch mask made of the silicon oxide layer on a lower surface of the silicon substrate; and
forming an ink ejection port of each of the nozzles such that the ink ejection port communicates with the damper by dry etching the lower surface of the silicon substrate using the third etch mask.

9. The method of claim 8, wherein the forming of the first etch mask comprises:
depositing parylene on the upper surface of the silicon substrate to form a parylene layer;
coating a first photoresist on a surface of the parylene layer and patterning the first photoresist to form a plurality of first openings corresponding to the plurality of restrictors;
selectively removing the parylene layer exposed through the first openings to partially expose the upper surface of the silicon substrate; and
removing the first photoresist.

10. The method of claim 9, wherein the selective removing of the parylene layer is performed by reactive ion etching or O₂ ashing.

11. The method of claim 8, wherein each of the first and second wet etching uses one of tetramethyl ammonium hydroxide and KOH as an etchant.

12. The method of claim 8, wherein a corner portion of each of the restrictors has a rounded shape.

13. The method of claim 8, wherein the forming of the second etch mask comprises:
forming a silicon oxide layer on the upper surface of the silicon substrate;
coating a second photoresist on an upper surface of the silicon oxide layer formed on the upper surface of the silicon substrate and patterning the second photoresist to form a plurality of second openings corresponding to the dampers;
selectively etching the silicon oxide layer exposed through the second openings to partially expose the upper surface of the silicon substrate; and
removing the second photoresist.

14. The method of claim 13, wherein the silicon oxide layer is formed by thermally oxidizing the silicon substrate.

15. The method of claim 13, wherein the etching of the silicon oxide layer is performed through reactive ion etching or wet etching using buffered oxide etchant.

16. The method of claim 8, wherein the forming of the third etch mask comprises:
forming a silicon oxide layer on the lower surface of the silicon substrate;
coating a third photoresist on a lower surface of the silicon oxide layer formed on the lower surface of the silicon substrate and patterning the third photoresist to form a plurality of third openings corresponding to the dampers;
selectively etching the silicon oxide layer exposed through the third openings to partially expose the lower surface of the silicon substrate; and
removing the third photoresist.

17. The method of claim 8, wherein the dry etching of the silicon substrate is performed using inductively coupled plasma reactive ion etching.

18. A method of wet etching a silicon substrate using a parylene mask, comprising:
depositing a parylene layer at room temperature on an upper surface of a silicon substrate;
forming a parylene mask by selectively etching portions of the parylene layer exposed through a photoresist; and
wet etching portions of the silicon substrate exposed through the parylene mask to a predetermined depth.

19. The method of claim 18, further comprising:
cleaning the at least one surface of the silicon substrate before depositing the parylene layer on the at least one surface.

20. The method of claim 19, wherein the at least one surface of the silicon substrate is cleaned using an organic cleaning method.

21. A method of forming a nozzle plate of a printhead, comprising:
forming a plurality of restrictors in a surface of a silicon substrate by wet etching portions of the silicon substrate exposed through a parylene mask, each restrictor having at least one rounded corner; and
forming a plurality of nozzles in the surface of the silicon by etching portions of the silicon substrate exposed through a second mask, each nozzle having a tapered shape.
